(19) United States
(12) Patent Application Publication
(10) Pub. No.: US 2023/0252199 A1
(43) Pub. Date: Aug. 10, 2023

(54) SYSTEM AND METHOD FOR A DIGITAL ENGINEERING TOOL FOR ENVIRONMENTAL SURVEILLANCE

(71) Applicant: Battelle Memorial Institute, Columbus, OH (US)

(72) Inventors: David Carl Glasbrenner, Hilliard, OH (US); James Ha, Aliso Viejo, CA (US); Eric Johnson, Columbus, OH (US); Jared Schuetter, Columbus, OH (US); Greg Mogilevsky, Owings Mills, MD (US); Megan W. Howard, Columbus, OH (US); Greg Zink, Hilliard, OH (US); David Charlson, Columbus, OH (US); Jim Risser, Lutherville Timonium, MD (US); Andrew Matas, Columbus, OH (US); Benjamin Cote, Powell, OH (US); Mason Mooney, Columbus, OH (US); Zachary Cotman, Columbus, OH (US)

(21) Appl. No.: 18/166,548

(22) Filed: Feb. 9, 2023

Related U.S. Application Data
(60) Provisional application No. 63/308,162, filed on Feb. 9, 2022.

(51) Int. Cl. G06F 30/13; G06F 30/27

(52) U.S. Cl. CPC G06F 30/13; G06F 30/27

(57) ABSTRACT

In an approach to environmental surveillance, a system includes one or more computer processors; one or more non-transitory computer readable storage media; and program instructions stored on the one or more non-transitory computer readable storage media for execution by at least one of the one or more computer processors. The program instructions include instructions to create a model of an environment; assign one or more devices to the model; input source data for the model, wherein the input source data is at least one of synthetic data and real data; determine events based on the one or more devices and the input source data; and create one or more outputs based on the events.

### CROSS-REFERENCE TO RELATED APPLICATIONS

The present application claims the benefit of the filing date of U.S. Provisional App. Serial No. 63/308,162, filed Feb. 09, 2022, the entire teachings of which application is hereby incorporated herein by reference.

### TECHNICAL FIELD

The present application relates generally to data processing systems and, more particularly, to a digital engineering tool for environmental surveillance.

### BACKGROUND

A monitoring system is software that helps system administrators monitor their infrastructure. These tools monitor system devices, traffic, and applications, and generate events and notifications when malfunctions and disruptions occur. Industrial monitoring refers to the collection and analysis of essential industrial data and statistics related to processes, assets and devices used in the industrial premises to improve productivity and quality.

Environmental monitoring describes the processes and activities that need to take place to characterize and monitor the quality of the environment. Environmental monitoring is used in the preparation of environmental impact assessments, as well as in many circumstances in which human activities carry a risk of harmful effects on the natural environment. All monitoring strategies and programs have reasons and justifications which are often designed to establish the current status of an environment or to establish trends in environmental parameters.

Artificial intelligence (AI) can be defined as the theory and development of computer systems able to perform tasks that normally require human intelligence, such as speech recognition, visual perception, decision-making, and translation between languages. The term AI is often used to describe systems that mimic cognitive functions of the human mind, such as learning and problem solving. Machine learning (ML) is a form of artificial intelligence that makes predictions from data.

### BRIEF DESCRIPTION OF THE DRAWINGS

Reference should be made to the following detailed description which should be read in conjunction with the following figures, wherein like numerals represent like parts.

FIG. 1 is a functional block diagram illustrating a distributed data processing environment, in accordance with an embodiment of the present disclosure.

FIG. 2 is a block diagram of the system input interfaces, in accordance with an embodiment of the present disclosure.

FIG. 3 is an example of a graphic user interface (GUI) for the digital engineering tool for environmental surveillance, in accordance with an embodiment of the present disclosure.

FIG. 4 is an example block diagram of the multi-layered analytics modeling for the digital engineering tool for environmental surveillance, in accordance with an embodiment of the present disclosure.

FIG. 5 is an example block diagram of one possible architecture of the digital engineering tool for environmental surveillance, in accordance with an embodiment of the present disclosure.

FIG. 6 depicts a block diagram of components of the computing device executing the virtual interface program within the distributed data processing environment of FIG. 1, in accordance with an embodiment of the present disclosure.

### DETAILED DESCRIPTION

The present disclosure is not limited in its application to the details of construction and the arrangement of components set forth in the following description or illustrated in the drawings. The examples described herein may be capable of other embodiments and of being practiced or being carried out in various ways. Also, it may be appreciated that the phraseology and terminology used herein is for the purpose of description and should not be regarded as limiting as would be apparent to those of ordinary skill in the art. Throughout the present description, like reference characters may indicate like structure throughout the several views, and such structure need not be separately discussed. Furthermore, any particular feature(s) of a particular exemplary embodiment may be equally applied to any other exemplary embodiment(s) of this specification as suitable. In other words, features between the various exemplary embodiments described herein are interchangeable, and not exclusive.

As used herein, the term device is understood to mean any device that may be monitored in a system, including sensors, e.g., temperature sensors, humidity sensors, environmental sensors, etc., but can also include conceptual devices such as cameras, audio monitors, etc. In addition, the term device may include virtual interfaces to devices, which may include virtual devices. For example, the term device may include a virtual interface to allow plug and play connection of a physical device, as well as modifications to devices already installed in the monitoring system; a schedule, e.g., a cleaning schedule, which may impact devices in the area being cleaned; weather; or people that may be in the area being monitored.

Chemical and biological threat integrated early warning (IEW) modeling has unique variables to overcome to provide real-time situational awareness, such as sifting through the plethora of harmless substances present in variable environments. Historically, the approach to assess IEW technologies has been to physically place a device in a location of interest and collect data over time in response to releases of surrogate agents. This process is costly, time consuming, and labor intensive, requiring repetition in each targeted venue for each sensor type as new technologies arise. To expedite this process and address gaps in IEW for chemical and biological detection modeling and implementation, there exists a need for a tool that can address these concerns. The system and computer-implemented method disclosed herein is a digital engineering tool for environmental surveillance that utilizes a graphical user interface (GUI) for scenario modeling and analytics that allows the end-user to virtually plug-and-play sensors and contextual data sources into a multilayer analytics platform at a user-defined geographic scale. The disclosed tool provides an iterative stepwise process of analysis with multiple opportunities for user input and feedback.

Detection of chemical and biological agents as they are introduced and circulate in our communities is critical for reducing the economic and societal impact upon our nation. The challenges in detecting these agents include the following. First, chemical and biological threat detection approaches need to sift through a sea of harmless substances that exist in the environment. Every location, be it indoor or outdoor, has unique environmental conditions that must be factored into the analysis. This creates a costly and time consuming test and evaluation endeavor determining which sensors to use, how many are required, and where to place them for each location.

Many systems exist that integrate disparate devices into a single cohesive system for environmental surveillance. Often these systems are not optimally designed with the flexibility to allow plug-and-play of new critical technology elements (CTEs) with new data streams based on higher-level analytics, since they are developed without extensive research and development in real world scenarios. In addition, it is time consuming and cost prohibitive to deploy a multitude of different devices in areas of interest to validate the decision-making of their algorithms and geographic placement. There exists a need for a plug and play method to integrate devices into an environment surveillance system and predict performance and optimal device geographic placement based on computer simulation.

The system disclosed herein is a flexible integrated device architecture that facilitates a virtual testbed to evaluate and/or validate performance of disparate devices, permit plug and play of novel CTEs, and predict optimal device geographic placement based on computer simulation. Source data for the system can be either computer-generated synthetically, based on real world data (e.g., hardware in the loop), or both. This architecture can also handle increasing data size from orthogonal devices, e.g., next generation sequencers, wearable low-cost sensors, and increasing amounts of data (raw or pre-processed) transmitted to the network, as well as non-orthogonal sensors, e.g., bio-aerosol sensors, radiation sensors, chemical sensors, etc. The disclosed system is a virtual tool and is not confined by the fiscal and physical limitations of real-world device testing. The system allows rapid plug and play of any device type, along with contextual data, in any location, at any scale (e.g., venue vs. region vs. jurisdiction), virtually. The system integrates data and events from multiple devices and orthogonal sources (e.g., humidity, temperature, video, etc.) into a singular output. The system supports data analysis conducted in a cloud or local-based system. GUI map tool permits virtual movement of devices with predicted implications to results.

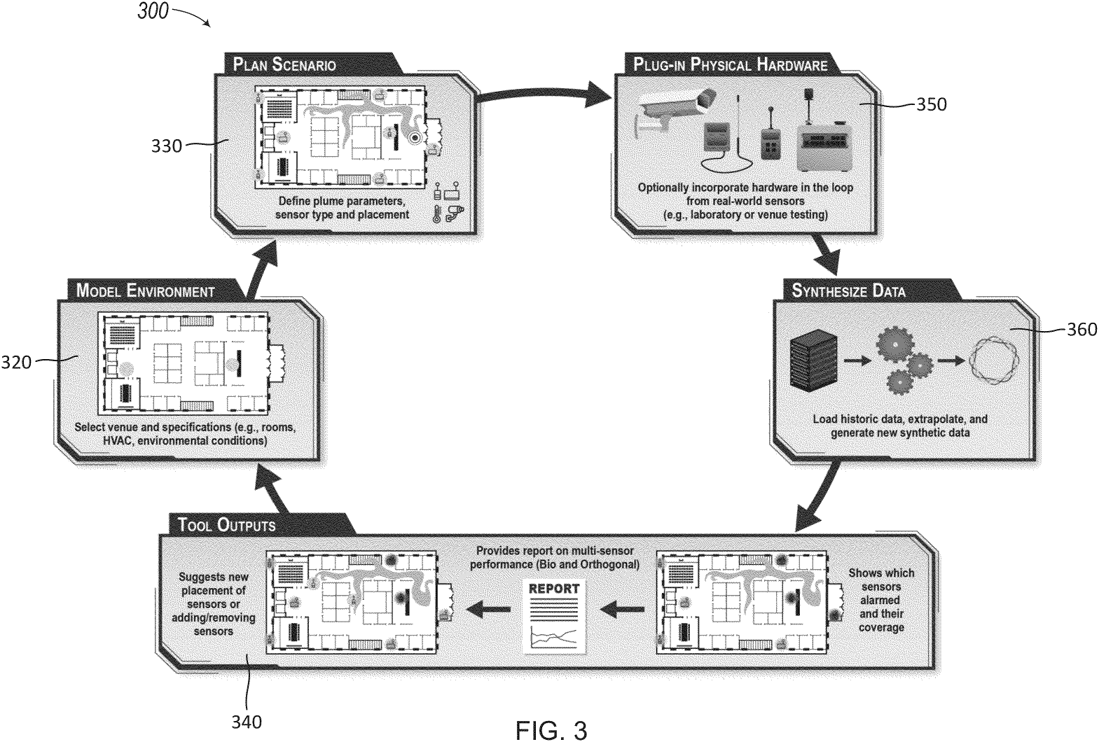

FIG. 3 is one exemplary embodiment of the digital engineering tool 300 for environmental surveillance. The example of FIG. 3 includes the functional blocks of one possible implementation of the system. It should be noted that the example of FIG. 3 is only one possible implementation for the digital engineering tool for environmental surveillance. Many different implementations are possible as would be apparent to one skilled in the art.

The digital engineering tool 300 allows end users to assess technologies and analytic tools against simulated scenarios to improve efficiency of system design and implementation. The digital engineering tool 300 is a multilayer analytics and integration platform with the ability to incorporate user-defined algorithms, integrate real sensors, real data, and synthetic data through machine learning, and provides data fusion of orthogonal data sources into a scenario.

When a user selects a location, model environment 320 may import or create a model of the location, e.g., a building floorplan. This may include, for example, the building location, and building specifications, such as number and size of rooms, Heating, Ventilation, and Air Conditioning (HVAC) systems, etc.

In some embodiments, the system may build a three dimensional computational fluid dynamics (CFD) model from a blueprint. Current systems require a user to manually create a blueprint, while the disclosed system automates that process by allowing the user to specify the CFD zone using a high-level description. The system takes a high-level description of the environment and performs the relevant calculations to construct the numerous low-level details and outputs the actual model file. For example, a rectangular room with a rectangular podium in its center can be described at a high level by a grid giving the relative height of the floor/podium at the corresponding points in the room. At the boundary of the podium, the system identifies the height differential and construct the required side walls.

With a more complex environment such as an arena, for example, there will be many such calculations, e.g., many rows of seats each at an increasing height, and the system may substantially reduce the time to construct the CFD model. A similar approach is used for the height of the space, which for an arena is not always a constant height. Further, as this low level detail is generated automatically it is not prone to user error, and the high-level description is easier to review to ensure that it properly represents the space being modeled. The disclosed system uses input Extensible Markup Language (XML) and comma-separated values (CSV) files that are laid out in a manner that someone with little background in CFD model can understand and use quickly. These files provide the high-level description of the environment, and the system may consume these files and create the resulting CFD representation of the space. The system performs the requisite calculations to transform the high-level description in the low-level detail that the CFD model requires.

Currently, CFD blueprint modeling using traditional means takes over forty hours to construct a simple area. The creation of an arena sized CFD model could take over a month without this system and would be incredibly tedious to create. For example, an arena may have over a thousand two-dimensional (2D) surfaces that each would have to be entered manually. Additionally, there is skill required to work with CFD models and fluid transport. The system automates a large part of making the CFD zone and will lower the skills required. The disclosed system increases the modeling speed significantly, typically completing 4-8 times, or more, faster, and once completed and updated, reduces the subject matter expert (SME) level required for the initial build. In some embodiments, the system may provide an interface wrapper to programmatically extract data in progress.

In plan scenario 330, the devices to be modeled within the environment chosen in model environment 320 are assigned. This may include types of devices and their placement, environmental conditions in the monitored area, sources of possible contamination, etc. The plug-in physical hardware module 350 optionally incorporates hardware in the loop from real-world sensors, e.g., laboratory or venue testing. As discussed above, the source data input into the model may be either real data, e.g., data generated by hardware in the loop, or synthetic data, i.e., data created by the system, for testing. If synthetic data is required, then the generate synthetic data 360 module will retrieve historical data for the device from the system database, extrapolate the historical data for the current environment, and create new synthetic data for the device based on the current environment. This process is described in more detail below.

The system runs a scenario on the devices and the environment to generate outputs. In this example, the outputs may include diagrams that show devices that have generated events, and the coverage area of those devices. The outputs may also include reports on the performance of the devices within the environment and may include suggested placement of devices, suggested device additions and/or suggested device removals. Outputs may also include false positive information and how contextual/orthogonal information informs on the detection events/report.

The system also includes a synthetic data simulator to generate synthetic data for a given device, based on real data taken by that device. When developing synthetic data, the user can choose to simulate any number of devices of different types. The synthetic data simulator will generate a dictionary giving the output of each device for each sample, where a sample is one device for one time step.

In one illustrative embodiment, the synthetic data simulator may include a device module, where the device module stores properties relevant to an individual device. The synthetic data simulator may also include a dataset module which drives the simulation and produces the final results to send to the next stage of the system. This module creates device objects for each device in the network. Then, at each time step, this module has each device create a sample and report back the results (a list of particles with simulated parameters). The dataset module combines these results from each device into a final dictionary that can be passed to the next level of the system.

To validate the synthetic data generation, the synthetic data simulator may create one or more holdout datasets which are not used for calibrating the synthetic data. The synthetic data simulator compares a simulation of the holdout dataset, with the holdout dataset itself. The comparison can be evaluated for statistical abnormalities or outliers.

The system also leverages AI across multiple devices to improve synthetic data generation and overall surveillance architecture suggestions, and to minimize false triggers, both false positive triggers and false negative triggers. For example, if one device indicates there is a positive hit, but another device does not, and it is determined the second device was a false negative, then AI may assist in learning why the second device showed a false negative and improve upon it on future runs. In some embodiments, the AI used may be machine learning. In other embodiments the AI used may be neural networks. The system also analyzes data for predictive maintenance in a virtual setting to reduce incurred costs upon real-world implementation.

The system disclosed also implements virtual interfaces with devices, and processes the raw or pre-processed data into a refined output. The virtual interfaces can interact with data through real data, e.g., a hardware in the loop physical connection or from real data that is just historical, or through interface with synthetic data generated separately. Within the virtual interface, machine learning algorithms may be implemented to learn and improve on the processing component to increase confidence in results. To this end, real-world and/or synthetic data can be stored and replayed through the pipeline to create multiple computer-generated scenario runs. The containerized process will be repeated for additional devices and contextual data sources and assembled as, for example, an orchestration tool. Higher level analytics through decision-making algorithms, anomaly detection algorithms and machine learning are implemented between the virtual interface outputs to increase confidence in events and reduce false positive instances. These algorithms may encompass any automated or human-assisted decision-making process derived from the data streams coming from the devices in the system.

The disclosed system accomplishes this by creating virtual interfaces for data sources and conducting initial processing within these separate digital components. This permits addition or removal of sensors without perturbing the larger system (i.e., allows plug and play of an end-user defined number of sensors and contextual data sources). The system adds storage and replay capabilities to leverage existing data sets to improve processing algorithms through machine learning training runs. The system integrates multiple user-selected sensor modalities and contextual non-sensor data to improve trigger event confidence.

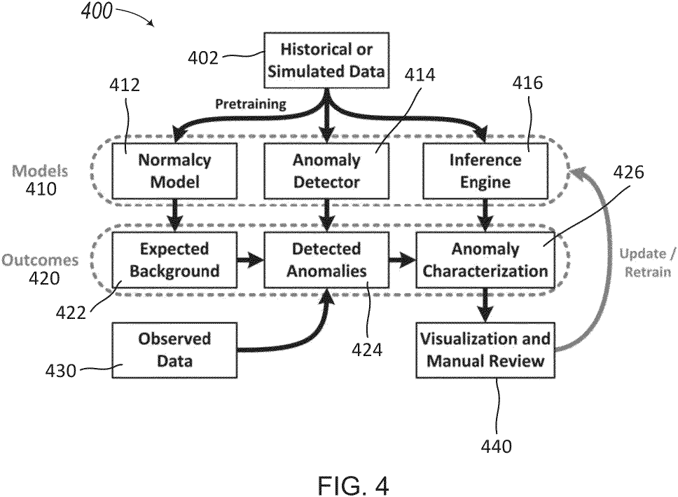

FIG. 4 is an example block diagram of the multi-layered analytics modeling 400 for the digital engineering tool for environmental surveillance, in accordance with an embodiment of the present disclosure. The multi-layered analytics modeling 400 includes input data 402, which may be actual historical data, or simulated data; models 410; outcomes 420; observed data 430; and output data including characterized anomalies 426.

The models 410 incorporates AI that may include three components, a normalcy model 412, an anomaly detector 414, and an inference engine 416. The normalcy model 412 relates network data sources and predicts the expected sensor background state 422. In various embodiments, the normalcy model 412 may use a Graph Neural Network (GNN), Bayesian network model, a Hidden Markov model, or any combination thereof. In some embodiments, the normalcy model 412 may use a multi-layer perceptron (MLP) neural network, i.e., a densely connected neural network, to accurately predict a background pattern. Testing of the MLP neural network in the normalcy model 412 validated the model and its ability to predict particle concentrations in time and space through statistical comparison to baseline truth data. This demonstrated that from a model trained on the concentrations observed at fixed time points, and fixed training sensor locations, the model can accurately interpolate/predict the concentration at any location and any time (within the conditions of the training data).

The normalcy model 412 may use either historical data, simulated data, or both to task the neural network models with specific goals that can be pretrained. The normalcy model 412 may input contextual information such as temperature and wind speed and direction, and predict a range of sensor outputs consistent with the background values observed under similar conditions. The agent detector will monitor the current state of the sensor network and observe when the conditions of the network move outside of the range predicted by the normalcy model, indicating the presence of non-background events. Finally, the inference engine will combine available information to determine the possible causes of an event. For example, if previously unobserved background conditions such as temperatures are higher than previously recorded, this information can be used to update the normalcy model.

The anomaly detector 414 is used to compare the expected sensor background state 422 to the observed data to detect anomalies 424. In some embodiments, the anomaly detector 414 may use thresholding, statistical process control, Bayesian inference, variational autoencoders, adversarial networks, or any combination thereof to detect anomalies.

The inference engine 416 is used to characterize the nature of the detected anomalies, especially those relating to potential threats. In some embodiments, the inference engine 416 may use statistical inference, entity relationship modeling, perturbation analysis (e.g., attention maps, LIME), of any combination thereof. Characterized anomalies 426 can be presented to a human for review 440 and for decision whether to respond or to update/retrain the models.

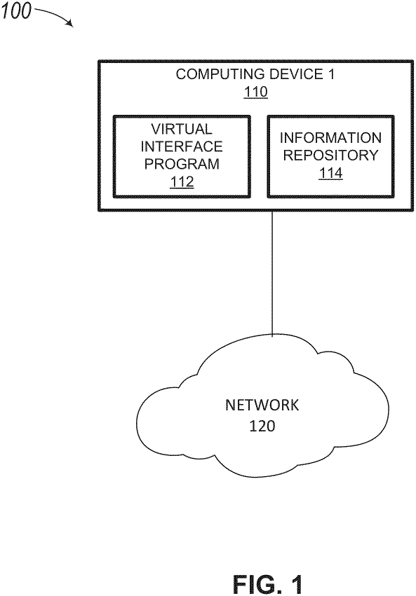

FIG. 1 is a functional block diagram illustrating a distributed data processing environment, generally designated 100, suitable for operation of the virtual interface program 112 in accordance with at least one embodiment of the present disclosure. The term “distributed” as used herein describes a computer system that includes multiple, physically distinct devices that operate together as a single computer system. FIG. 1 provides only an illustration of one implementation and does not imply any limitations with regard to the environments in which different embodiments may be implemented. Many modifications to the depicted environment may be made by those skilled in the art without departing from the scope of the disclosure as recited by the claims.

Distributed data processing environment 100 includes computing device 110 optionally connected to network 120. While the illustrated example distributed processing environment 100 shows one computing device, the actual system may have any number of computing devices attached via network 120.

Network 120 can be, for example, a telecommunications network, a local area network (LAN), a wide area network (WAN), such as the Internet, or a combination of the three, and can include wired, wireless, or fiber optic connections. Network 120 can include one or more wired and/or wireless networks that are capable of receiving and transmitting data, voice, and/or video signals, including multimedia signals that include voice, data, and video information. In general, network 120 can be any combination of connections and protocols that will support communications between computing device 110 and other computing devices (not shown) within distributed data processing environment 100.

Computing device 110 can be a standalone computing device, a management server, a web server, a mobile computing device, or any other electronic device or computing system capable of receiving, sending, and processing data. In embodiment, computing device 110 can be a laptop computer, a tablet computer, a netbook computer, a personal computer (PC), a desktop computer, a smart phone, or any programmable electronic device capable of communicating with other computing devices (not shown) within distributed data processing environment 100 via network 120. In another embodiment, computing device 110 can represent a server computing system utilizing multiple computers as a server system, such as in a cloud computing environment. In yet another embodiment, computing device 110 represents a computing system utilizing clustered computers and components (e.g., database server computers, application server computers) that act as a single pool of seamless resources when accessed within distributed data processing environment 100.

In an embodiment, computing device 110 includes the virtual interface program 112. In an embodiment, the virtual interface program 112 is a program, application, or subprogram of a larger program for a digital engineering tool for environmental surveillance. In an alternative embodiment, the virtual interface program 112 may be located on any other device accessible by computing device 110 via network 120.

In an embodiment, computing device 110 includes information repository 114. In an embodiment, information repository 114 may be managed by the virtual interface program 112. In an alternate embodiment, information repository 114 may be managed by the operating system of the computing device 110, alone, or together with, the virtual interface program 112. Information repository 114 is a data repository that can store, gather, compare, and/or combine information. In some embodiments, information repository 114 is located externally to computing device 110 and accessed through a communication network, such as network 120. In some embodiments, information repository 114 is stored on computing device 110. In some embodiments, information repository 114 may reside on another computing device (not shown), provided that information repository 114 is accessible by computing device 110. Information repository 114 includes, but is not limited to, device configuration data, server configuration data, testbed configuration data, system data, container data, device status data, machine learning training data, and other data that is received by the virtual interface program 112 from one or more sources, and data that is created by the virtual interface program 112.

Information repository 114 may be implemented using any non-transitory volatile or non-volatile storage media for storing information, as known in the art. For example, information repository 114 may be implemented with random-access memory (RAM), semiconductor memory, solid-state drives (SSD), one or more independent hard disk drives, multiple hard disk drives in a redundant array of independent disks (RAID), or an optical disc. Similarly, information repository 114 may be implemented with any suitable storage architecture known in the art, such as a relational database, an object-oriented database, or one or more tables.

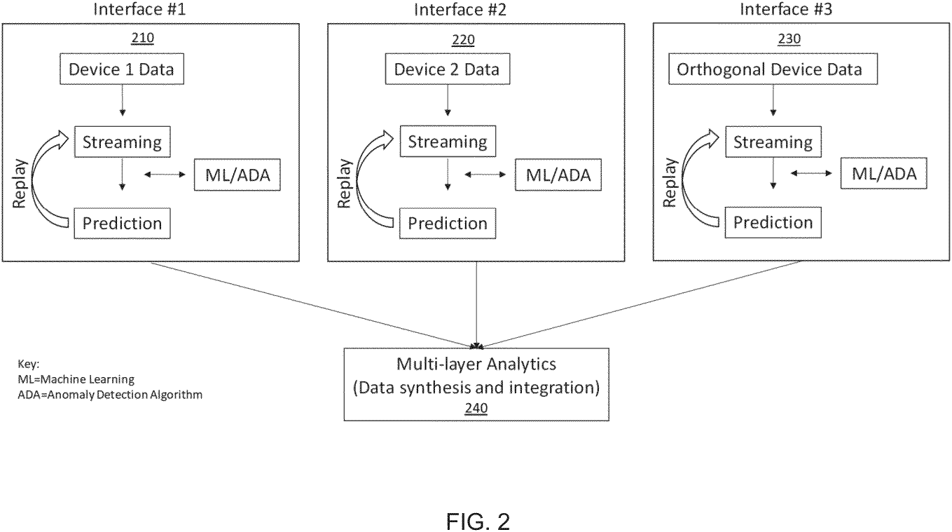

FIG. 2 is a block diagram of the system input interfaces, in accordance with an embodiment of the present disclosure. The block diagram of FIG. 2 includes three example interfaces, interface #1 210, interface #2 220, and interface #3 230. Although three interfaces are shown in the example system of FIG. 2 any number of interfaces may be included in the system, as would be apparent to those of ordinary skill in the art. The example system of FIG. 2 also includes multi-layer analytics 240.

In the example system input interfaces, data from an actual device is streamed to a prediction algorithm. A replay capability allows the same recorded data to be streamed again so that the prediction from different prediction algorithms can be evaluated and tested to create the ideal Anomaly Detection Algorithm (ADA) using ML or other algorithms.

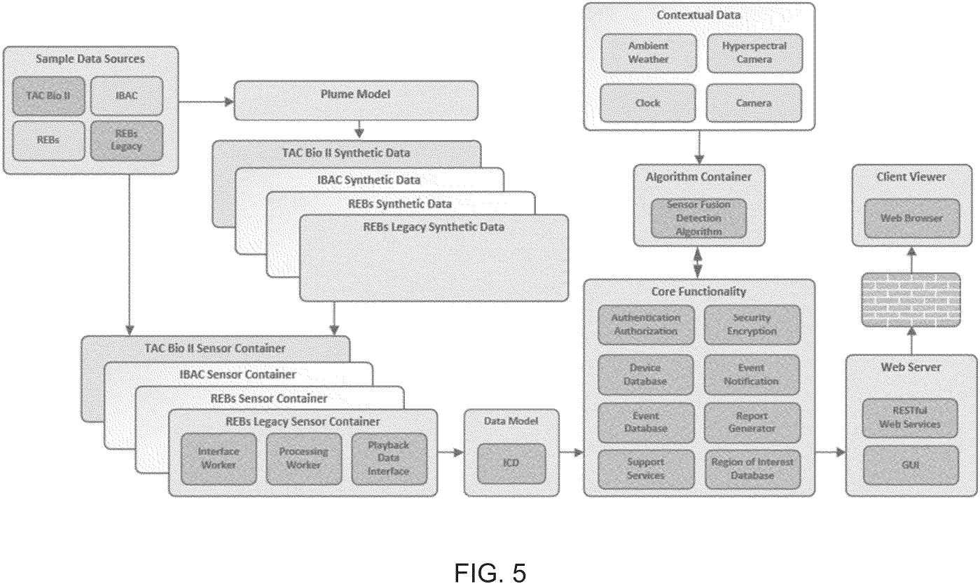

FIG. 5 is an example block diagram of one possible architecture of the digital engineering tool for environmental surveillance, in accordance with an embodiment of the present disclosure. The example illustrated in FIG. 5 shows a possible architecture for the digital engineering tool for environmental surveillance as might be used in a system for biohazard surveillance. It should be noted, however, that while the example of FIG. 5 is a system for biohazard surveillance, the system disclosed is not limited to biohazard surveillance, and the example of FIG. 5 is only one possible architecture for one possible application of the digital engineering tool for environmental surveillance. Many different architectures and many different applications are possible as would be apparent to one skilled in the art.

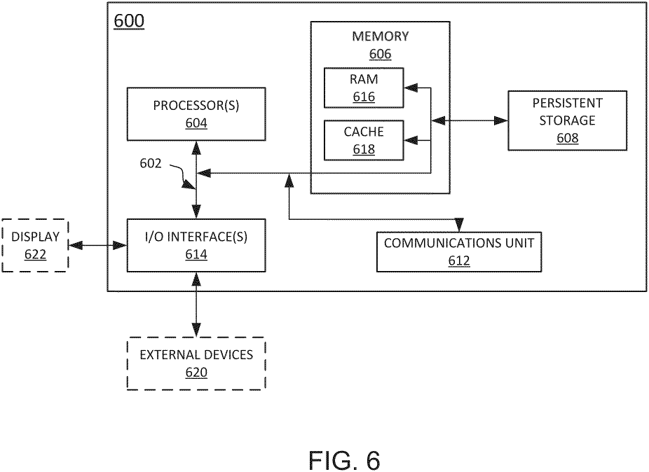

FIG. 6 is a block diagram depicting components of one example of the computing device 110 suitable for virtual interface program, within the distributed data processing environment of FIG. 1, consistent with the present disclosure. FIG. 6 displays the computing device or computer 600, one or more processor(s) 604 (including one or more computer processors), a communications fabric 602, a memory 606 including, a random-access memory (RAM) 616 and a cache 618, a persistent storage 608, a communications unit 612, I/O interfaces 614, a display 622, and external devices 620. It should be appreciated that FIG. 6 provides only an illustration of one embodiment and does not imply any limitations with regard to the environments in which different embodiments may be implemented. Many modifications to the depicted environment may be made.

As depicted, the computer 600 operates over the communications fabric 602, which provides communications between the computer processor(s) 604, memory 606, persistent storage 608, communications unit 612, and input/output (I/O) interface(s) 614. The communications fabric 602 may be implemented with an architecture suitable for passing data or control information between the processors 604 (e.g., microprocessors, communications processors, and network processors), the memory 606, the external devices 620, and any other hardware components within a system. For example, the communications fabric 602 may be implemented with one or more buses.

The memory 606 and persistent storage 608 are computer readable storage media. In the depicted embodiment, the memory 606 comprises a RAM 616 and a cache 618. In general, the memory 606 can include any suitable volatile or non-volatile computer readable storage media. Cache 618 is a fast memory that enhances the performance of processor(s) 604 by holding recently accessed data, and near recently accessed data, from RAM 616.

Program instructions for virtual interface program may be stored in the persistent storage 608, or more generally, any computer readable storage media, for execution by one or more of the respective computer processors 604 via one or more memories of the memory 606. The persistent storage 608 may be a magnetic hard disk drive, a solid-state disk drive, a semiconductor storage device, flash memory, read only memory (ROM), electronically erasable programmable read-only memory (EEPROM), or any other computer readable storage media that is capable of storing program instruction or digital information.

The media used by persistent storage 608 may also be removable. For example, a removable hard drive may be used for persistent storage 608. Other examples include optical and magnetic disks, thumb drives, and smart cards that are inserted into a drive for transfer onto another computer readable storage medium that is also part of persistent storage 608.

The communications unit 612, in these examples, provides for communications with other data processing systems or devices. In these examples, the communications unit 612 includes one or more network interface cards. The communications unit 612 may provide communications through the use of either or both physical and wireless communications links. In the context of some embodiments of the present disclosure, the source of the various input data may be physically remote to the computer 600 such that the input data may be received, and the output similarly transmitted via the communications unit 612.

The I/O interface(s) 614 allows for input and output of data with other devices that may be connected to computer 600. For example, the I/O interface(s) 614 may provide a connection to external device(s) 620 such as a keyboard, a keypad, a touch screen, a microphone, a digital camera, and/or some other suitable input device. External device(s) 620 can also include portable computer readable storage media such as, for example, thumb drives, portable optical or magnetic disks, and memory cards. Software and data used to practice embodiments of the present disclosure, e.g., virtual interface program, can be stored on such portable computer readable storage media and can be loaded onto persistent storage 608 via the I/O interface(s) 614. I/O interface(s) 614 also connect to a display 622.

Display 622 provides a mechanism to display data to a user and may be, for example, a computer monitor. Display 622 can also function as a touchscreen, such as a display of a tablet computer.

Machine learning is an application of AI that creates systems that have the ability to automatically learn and improve from experience. ML involves the development of computer programs that can access data and learn based on that data. ML algorithms typically build mathematical models based on sample, or training, data in order to make predictions or decisions without being explicitly programmed to do so. The use of training data in ML requires human intervention for feature extraction in creating the training data set. The two main types of ML are Supervised learning and Unsupervised learning. Supervised learning uses labeled datasets that are designed to train or “supervise” algorithms into classifying data or predicting outcomes accurately. Supervised learning is typically used for problems requiring classification or regression analysis. Classification problems use an algorithm to accurately assign test data into specific categories. Regression is a method that uses an algorithm to understand the relationship between dependent and independent variables. Regression models are helpful for predicting numerical values based on different data points.

Unsupervised learning uses machine learning algorithms to analyze and cluster unlabeled datasets. These algorithms discover hidden patterns or data groupings without the need for human intervention, and their ability to discover similarities and differences in information make unsupervised learning the ideal solution for exploratory data analysis, cross-selling strategies, customer segmentation, and image recognition. Unsupervised learning is typically used for problems requiring clustering, e.g., K-means clustering, or association, which uses different rules to find relationships between variables in a given dataset.

Deep learning is a sub-field of ML that automates much of the feature extraction, eliminating some of the manual human intervention required and enabling the use of larger data sets. Deep learning typically uses neural networks, which are highly interconnected entities, called nodes. Each node, or artificial neuron, connects to another and has an associated weight and threshold. A node multiplies the input data with the weight, which either amplifies or dampens that input, thereby assigning significance to inputs with regard to the task the algorithm is trying to learn. If the output of any individual node is above the specified threshold value, that node is activated, sending data to the next layer of the network. Otherwise, no data is passed along to the next layer of the network. A neural network that consists of more than three layers can be considered a deep learning algorithm or a deep neural network.

According to one aspect of the disclosure there is thus provided a system for environmental surveillance. The system includes one or more computer processors; one or more non-transitory computer readable storage media; and program instructions stored on the one or more non-transitory computer readable storage media for execution by at least one of the one or more computer processors. The program instructions include instructions to create a model of an environment; assign one or more devices to the model; input source data for the model, wherein the input source data is at least one of synthetic data and real data; determine events based on the one or more devices and the input source data; and create one or more outputs based on the events.

According to another aspect of the disclosure, there is provided a method of environmental surveillance, including: creating, by one or more computer processors, a model of an environment; assigning, by the one or more computer processors, one or more devices to the model; inputting, by the one or more computer processors, source data for the model, wherein the source data is at least one of synthetic data and real data; determining, by the one or more computer processors, events based on the one or more devices and the source data; and creating, by the one or more computer processors, one or more outputs based on the events.

The programs described herein are identified based upon the application for which they are implemented in a specific embodiment of the disclosure. However, it should be appreciated that any particular program nomenclature herein is used merely for convenience, and thus the disclosure should not be limited to use solely in any specific application identified and/or implied by such nomenclature.

The present disclosure may be a system, a method, and/or a computer program product. The system or computer program product may include non-transitory computer readable storage media having computer readable program instructions thereon for causing a processor to carry out aspects of the present disclosure.

The non-transitory computer readable storage media can be any tangible device that can retain and store instructions for use by an instruction execution device. The non-transitory computer readable storage media may be, for example, but is not limited to, an electronic storage device, a magnetic storage device, an optical storage device, an electromagnetic storage device, a semiconductor storage device, or any suitable combination of the foregoing. A non-exhaustive list of more specific examples of the non-transitory computer readable storage media includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A non-transitory computer readable storage media, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a non-transitory computer readable storage media or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a non-transitory computer readable storage media within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or other programmable logic devices (PLD) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, a special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a non-transitory computer readable storage media that can direct a computer, a programmable data processing apparatus, and/or other devices to function in a particular manner, such that the non-transitory computer readable storage media having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operations to be performed on the computer, other programmable apparatus, or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the disclosure. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A system for environmental surveillance, the system comprising:
one or more computer processors;
one or more non-transitory computer readable storage media; and
program instructions stored on the one or more non-transitory computer readable storage media for execution by at least one of the one or more computer processors to:
create a model of an environment;
assign one or more devices to the model;
input a source data for the model, wherein the source data is at least one of synthetic data and real data;
determine events based on the one or more devices and the source data; and
create one or more outputs based on the events.

2. The system of claim 1, wherein create the model of the environment further comprises:
receive a high-level description of the environment;
construct one or more low-level details of the environment; and
output the model based on the low-level details.

3. The system of claim 2, wherein the high-level description of the environment is a two-dimensional blueprint.

4. The system of claim 1, wherein assign the one or more devices to the model further comprises:
assign each device of the one or more devices to a virtual interface of a plurality of virtual interfaces; and
assign each device of the one or more devices to a location in the environment.

5. The system of claim 2, further comprising Artificial Intelligence (AI) to improve decision-making and prediction, wherein the AI is selected from the group consisting of a Graph Neural Network (GNN), a Bayesian network model, a Hidden Markov model, a multi-layer perceptron (MLP) neural network, or combinations thereof.

6. The system of claim 4, wherein data from orthogonal sources and contextual data is utilized to improve decision-making and prediction from the virtual interface.

7. The system of claim 1, wherein create the model of the environment further comprises:
determine a location of the environment;
determine one or more specifications of the environment; and
import the model of the environment.

8. The system of claim 1, wherein create the model of the environment further comprises:
determine a location of the environment;
determine one or more specifications of the environment; and
create the model of the environment.

9. The system of claim 1, wherein the source data is at least one of synthetic data and real data further comprises:
responsive to the source data is synthetic data, retrieve historical data for the one or more devices;
extrapolate the historical data based on the environment; and
generate the synthetic data from the historical data.

10. The system of claim 1, wherein the one or more outputs include at least one of device events, device performance, predict optimal device geographic placement, suggested device additions, and suggested device removals.

11. A computer-implemented method for environmental surveillance, the computer-implemented method comprising:
creating, by one or more computer processors, a model of an environment;
assigning, by the one or more computer processors, one or more devices to the model;
inputting, by the one or more computer processors, source data for the model, wherein the source data is at least one of synthetic data and real data;
determining, by the one or more computer processors, events based on the one or more devices and the source data; and
creating, by the one or more computer processors, one or more outputs based on the events.

12. The computer-implemented method of claim 11, wherein create the model of the environment further comprises:
receiving, by the one or more computer processors, a high-level description of the environment;
constructing, by the one or more computer processors, one or more low-level details of the environment; and
outputting, by the one or more computer processors, the model based on the low-level details.

13. The computer-implemented method of claim 12, wherein the high-level description of the environment is a two-dimensional blueprint.

14. The computer-implemented method of claim 11, wherein assign the one or more devices to the model further comprises:
assigning, by the one or more computer processors, each device of the one or more devices to a virtual interface of a plurality of virtual interfaces; and
assigning, by the one or more computer processors, each device of the one or more devices to a location in the environment.

15. The computer-implemented method of claim 12, further comprising Artificial Intelligence (AI) to improve decision-making and prediction, wherein the AI is selected from the group consisting of a Graph Neural Network (GNN), a Bayesian network model, a Hidden Markov model, a multi-layer perceptron (MLP) neural network, or combinations thereof.

16. The computer-implemented method of claim 14, wherein data from orthogonal sources and contextual data is utilized to improve decision-making and prediction from the virtual interface.

17. The computer-implemented method of claim 11, wherein creating the model of the environment further comprises:
determining, by the one or more computer processors, a location of the environment;
determining, by the one or more computer processors, one or more specifications of the environment; and
importing, by the one or more computer processors, the model of the environment.

18. The computer-implemented method of claim 11, wherein creating the model of the environment further comprises:
determining, by the one or more computer processors, a location of the environment;
determining, by the one or more computer processors, one or more specifications of the environment; and
creating, by the one or more computer processors, the model of the environment.

19. The computer-implemented method of claim 11, wherein inputting the source data for the model, wherein the source data is at least one of synthetic data and real data further comprises:
responsive to the source data is synthetic data, retrieving, by the one or more computer processors, historical data for the one or more devices;
extrapolating, by the one or more computer processors, the historical data based on the environment; and
generating, by the one or more computer processors, the synthetic data from the historical data.

20. The computer-implemented method of claim 11, wherein the one or more outputs include at least one of device events, device performance, predict optimal device geographic placement, suggested device additions, and suggested device removals.
